(19) United States
(12) Patent Application Publication
(10) Pub. No.: US 2025/0275457 A1
(43) Pub. Date: Aug. 28, 2025

(54) DISPLAY APPARATUS

(71) Applicant: LG Display Co., Ltd., Seoul (KR)

(72) Inventor: Yongju KIM, Goyang-si (KR)

(73) Assignee: LG Display Co., Ltd., Seoul (KR)

(21) Appl. No.: 19/045,260

(22) Filed: Feb. 4, 2025

(30) Foreign Application Priority Data
Feb. 22, 2024 (KR) 10-2024-0025572

(51) Int. Cl. H10K 59/80; H10H 29/855

(52) U.S. Cl. CPC H10K 59/8793; H10H 29/855

(57) ABSTRACT

A display apparatus can include a display panel having an active area and a non-active area, and a polarizer disposed on the display panel, The non-active area includes a first non-active area adjacent to at least a part of the active area, and a second non-active area extending from the first non-active area to be bent. The polarizer includes a plurality of concave portions disposed between the active area and the second non-active area, in the first non-active area. Accordingly, the deformation of the polarizer can be minimized, reduced or prevented.

### CROSS-REFERENCE TO RELATED APPLICATIONS

This application claims priority to Korean Patent Application No. 10-2024-0025572 filed in the Republic of Korea on Feb. 22, 2024, the entire disclosure of which is hereby expressly incorporated by reference into the present application.

### BACKGROUND

### Technical Field

The present disclosure relates to a display apparatus, and more particularly, for example, without limitation, to a display apparatus in which deformation of a polarizer is minimized, reduced or prevented.

### Discussion of the Related Art

An application range of a liquid crystal display and a light emitting display apparatus being widely used for now is gradually expanding.

A light emitting display apparatus does not require a separate light source. Therefore, the light emitting display apparatus can be manufactured to be light and thin and has process advantages and has low power consumption in accordance with the low voltage driving. The light emitting display apparatus includes a self-emitting element and includes layers formed of organic thin films so that the flexibility and elasticity are superior to the other display apparatuses.

The description provided in the background section should not be assumed to be prior art merely because it is mentioned in or associated with the background section. The background section can include information that describes one or more aspects of the subject technology.

### SUMMARY OF THE DISCLOSURE

An aspect of the present disclosure is to provide a display apparatus in which deformation of a polarizer is minimized, reduced or prevented.

Another aspect of the present disclosure is to provide a display apparatus in which moisture permeation due to contraction of the polarizer can be minimized, suppressed or prevented.

Still another aspect of the present disclosure is to provide a display apparatus in which a curl phenomenon due to the direction difference of contraction and expansion of the polarizer can be minimized, reduced or prevented.

Still another aspect of the present disclosure is to provide a display apparatus with improved reliability and display quality.

Aspects of the present disclosure are not limited to the above-mentioned aspects, and other aspects, which are not mentioned above, can be clearly understood by those skilled in the art from the following descriptions.

To achieve these and other aspects of the inventive concepts, as embodied and broadly described herein, a display apparatus includes a display panel including an active area and a non-active area and a polarizer disposed on the display panel, wherein the non-active area includes a first non-active area adjacent to at least a part of the active area, and a second non-active area extending from the first non-active area to be bent, and the polarizer includes a plurality of concave portions disposed between the active area and the second non-active area, in the first non-active area. Accordingly, the deformation of the polarizer can be minimized, reduced or prevented.

Other detailed matters of the example embodiments of the present disclosure are included in the detailed description and the drawings.

According to the example embodiments of the present disclosure, a polarizer includes a plurality of concave portions to minimize, reduce or prevent the deformation of the polarizer.

According to the example embodiment of the present disclosure, a plurality of concave portions of the polarizer is disposed on the boundary of a bending area and a non-bending area to minimize, reduce or prevent deformation of the polarizer due to the bending stress.

According to the example embodiment of the present disclosure, the moisture permeation due to the contraction of the polarizer is suppressed, minimized or prevented.

According to the example embodiment of the present disclosure, the lifting of the polarizer due to the curl phenomenon of the polarizer is suppressed, minimized or prevented.

According to the example embodiment of the present disclosure, the reliability and the display quality can be improved.

According to the example embodiment of the present disclosure, the possibility of potential defects, such as image quality defects of the display apparatus is minimized, reduced or prevented to improve the lifespan of the display apparatus, thereby enabling low power operation in terms of reduction of a production energy.

The effects according to the present disclosure are not limited to the contents exemplified above, and more various effects are included in the present disclosure.

It is to be understood that both the foregoing general description and the following detailed description are example and explanatory and are intended to provide further explanation of the inventive concepts as claimed.

### BRIEF DESCRIPTION OF THE DRAWINGS

The accompanying drawings, that can be included to provide a further understanding of the disclosure and can be incorporated in and constitute a part of the disclosure, illustrate embodiments of the disclosure and together with the description serve to explain various principles of the disclosure.

The above and other aspects, features and other advantages of the present disclosure will be more clearly understood from the following detailed description taken in conjunction with the accompanying drawings, in which:

FIG. 1 is a diagram of a display apparatus according to one or more example embodiments of the present disclosure;

FIG. 2 is a plan view of a display apparatus according to an example embodiment of the present disclosure;

FIGS. 3A and 3B are an enlarged view and a perspective view of an area A of FIG. 2;

FIGS. 4A and 4B are cross-sectional views of a display apparatus according to an example embodiment of the present disclosure; and

FIG. 5 is a schematic plan view of a display apparatus according to another example embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted or briefly provided. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations can be selected only for convenience of writing the disclosure and can be thus different from those used in actual products.

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, areas, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted or briefly provided to avoid unnecessarily obscuring the subject matter of the present disclosure. The terms such as “including,” “comprising,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

The word “example” is used to mean serving as an example or illustration. Embodiments are example embodiments. Aspects are example aspects. “Embodiments,” “examples,” “aspects,” and the like should not be construed to be preferred or advantageous over other implementations. An embodiment, an example, an example embodiment, an aspect, or the like can refer to one or more embodiments, one or more examples, one or more example embodiments, one or more aspects, or the like, unless stated otherwise. Further, the term “may” encompasses all the meanings of the term “can”.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts can be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

When an element or layer is disposed “on” another element or layer, another layer or another element can be interposed directly on the other element or therebetween.

Although the terms “first”, “second”, “A”, “B”, “(a)”, “(b)” and the like are used for describing various components, these components are not confined by these terms. These terms are merely used for distinguishing one component from the other components. Therefore, a first component to be mentioned below can be a second component in a technical concept of the present disclosure. Further, when an element or layer is described as being “connected,” “coupled,” or “adhered” to another element or layer, the element or layer can not only be directly connected, or adhered to that other element or layer, but also be indirectly connected, or adhered to that other another element or layer with one or more intervening elements or layers “disposed” between the elements or layers, unless otherwise specified.

Like reference numerals generally denote like elements throughout the disclosure.

A size and a thickness of each component illustrated in the drawing are illustrated for convenience of description, and the present disclosure is not limited to the size and the thickness of the component illustrated.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element. Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

A transistor used in a display device according to example embodiments of the present disclosure can be implemented as any one transistor of an n-channel transistor (NMOS) and a p-channel transistor (PMOS). The transistor can be implemented as an oxide semiconductor transistor having an oxide semiconductor as an active layer or a low temperature poly-silicon (LTPS) transistor having LTPS as the active layer. The transistor can at least include a gate electrode, a source electrode, and a drain electrode. The transistor can be implemented as a thin film transistor (TFT) on a display panel. A carrier in the transistor flows from a source electrode to a drain electrode. In the case of the n-channel transistor (NMOS), since the carrier is an electron, a source voltage can be lower than a drain voltage so that the electron can flow from the source electrode to the drain electrode. In the n-channel transistor (NMOS), a current can flow from the drain electrode to the source electrode, and the source electrode can be an output terminal. In the case of the p-channel transistor (PMOS), since the carrier is a hole, the source voltage can be higher than the drain voltage so that the hole can flow from the source electrode to the drain electrode. Since the hole flows from the source electrode to the drain electrode in the p-channel transistor (PMOS), the current can flow from a source electrode to a drain electrode, and the drain electrode can be the output terminal. Accordingly, it should be noted that since the source and the drain can be changed according to an applied voltage, the source and the drain of the transistor are not fixed. In the present disclosure, a description is made by assuming that the transistor is the n-channel transistor (NMOS), but the present disclosure is not limited thereto, but the p-channel transistor can be used, and as a result, a circuit configuration can also be changed.

Hereinafter, a display apparatus according to example embodiments of the present disclosure will be described in detail with reference to accompanying drawings. All the components of each display apparatus according to all embodiments of the present disclosure are operatively coupled and configured.

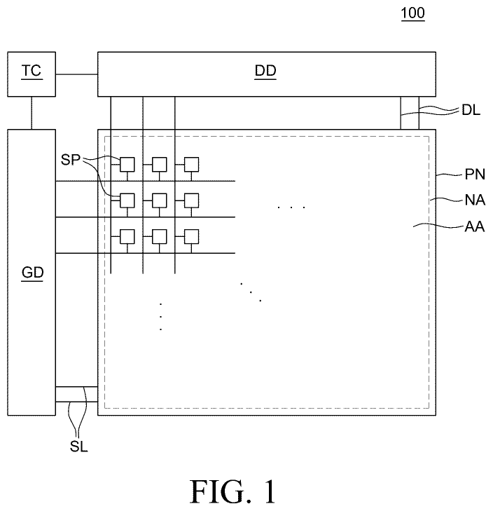

FIG. 1 is a schematic diagram of a display apparatus according to one or more example embodiments of the present disclosure.

In FIG. 1, for the convenience of description, among various components of a display apparatus 100, a display panel PN, a gate driver GD, a data driver DD, and a timing controller TC are illustrated.

Referring to FIG. 1, the display apparatus 100 includes the display panel PN including a plurality of sub-pixels SP, the gate driver GD and the data driver DD which supply various signals to the display panel PN, and the timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto. For example, the gate driver GD can be disposed at one or two sides of the display panel PN in a Gate in Panel (GIP) manner, or can be disposed within the display area of the display panel PN in a gate-in-active area (GIA) manner, and the present disclosure is not limited thereto.

The data driver DD converts image data input from the timing controller TC into a data voltage using a reference gamma voltage in accordance with a plurality of data control signals supplied from the timing controller TC. The data driver DD can supply the converted data voltage to the plurality of data lines DL.

The timing controller TC aligns image data input from the outside to supply the image data to the data driver DD. The timing controller TC can generate a gate control signal and a data control signal using synchronization signals input from the outside, such as a dot clock signal, a data enable signal, and horizontal/vertical synchronization signals. In addition, the timing controller TC supplies the generated gate control signal and data control signal to the gate driver GD and the data driver DD, respectively, to control the gate driver GD and the data driver DD.

The display panel PN is a configuration which displays images to the user and includes the plurality of sub-pixels SP. In the display panel PN, the plurality of scan lines SL and the plurality of data lines DL intersect each other and the plurality of sub-pixels SP is connected to the scan lines SL and the data lines DL, respectively. In addition, each of the plurality of sub-pixels SP is connected to a high potential power line, a low potential power line, and a reference line.

In the display panel PN, an active area AA (or display area) and a non-active area NA (or non-display area) adjacent to (for example, enclosing) at least a part of the active area AA can be defined. The active area AA is an area in which images are displayed in the display apparatus 100. In the active area AA, a plurality of sub-pixels SP which configures a plurality of pixels PX and a circuit (or a pixel circuit) for driving the plurality of sub-pixels SP can be disposed. The plurality of sub-pixels SP is a minimum unit which configures the active area AA and n sub-pixels SP form one pixel. In each of the plurality of sub-pixels SP, a light emitting diode and a thin film transistor for driving the light emitting diode can be disposed. The plurality of light emitting diodes can be defined in different manners depending on the type of the display panel PN. For example, when the display panel PN is a light emitting display panel, the light emitting diode can be an organic light emitting diode (OLED) or an inorganic light emitting diode (M-LED). The example embodiments of the present disclosure are not limited thereto.

In the active area AA, a plurality of wiring lines which transmits various signals to the plurality of sub-pixels SP is disposed. For example, the plurality of wiring lines includes a plurality of data lines DL which supplies a data voltage to each of the plurality of sub-pixels SP and a plurality of scan lines SL which supplies a scan signal to each of the plurality of sub-pixels SP. The plurality of scan lines SL extends to one direction in the active area AA to be connected to the plurality of sub-pixels SP and the plurality of data lines DL extends to a direction different from the one direction in the active area AA to be connected to the plurality of sub-pixels SP. In addition, in the active area AA, a low potential power line and a high potential power line can be further disposed, but are not limited thereto.

The non-active area NA is an area where images are not displayed so that the non-active area NA can be defined as an area extending from the active area AA. In the non-active area NA, a link line which transmits a signal to the sub-pixel SP of the active area AA, a pad electrode, or a driving IC, such as a gate driver IC or a data driver IC, can be disposed.

In addition, the non-active area NA can be located on a rear surface of the display panel PN, for example, a surface on which the sub-pixels SP are not disposed or can be omitted, and is not limited as illustrated in the drawings.

In addition, the drive circuits such as the gate driver GD, the data driver DD, and the timing controller TC can be connected to the display panel PN in various ways. For example, the gate driver GD can be mounted in the non-display area NA by a gate-in-panel (GIP) method or mounted between the plurality of sub-pixels SP by a gate-in-active area (GIA) method in the display area AA.

For example, the data driver DD and the timing controller TC can be formed on a separate flexible film and a printed circuit board and electrically connect the display panel PN, the data driver DD, and the timing controller TC by a method of bonding the flexible film and the printed circuit board to a pad electrode formed in the non-display area NA of the display panel PN.

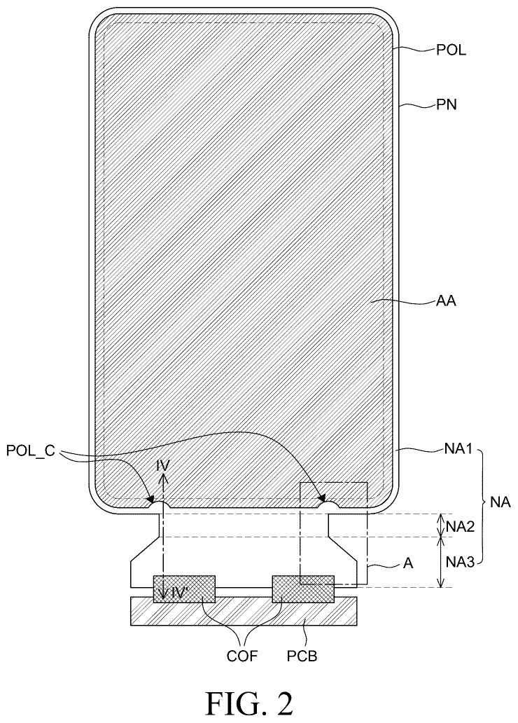

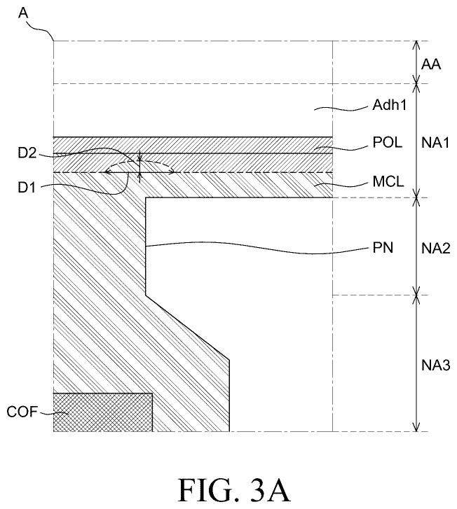

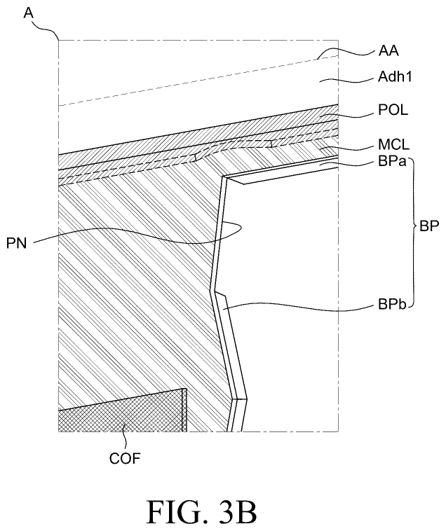

FIG. 2 is a plan view of a display apparatus according to an example embodiment of the present disclosure. FIGS. 3A and 3B are respectively an enlarged view and a perspective view of an area A of FIG. 2.

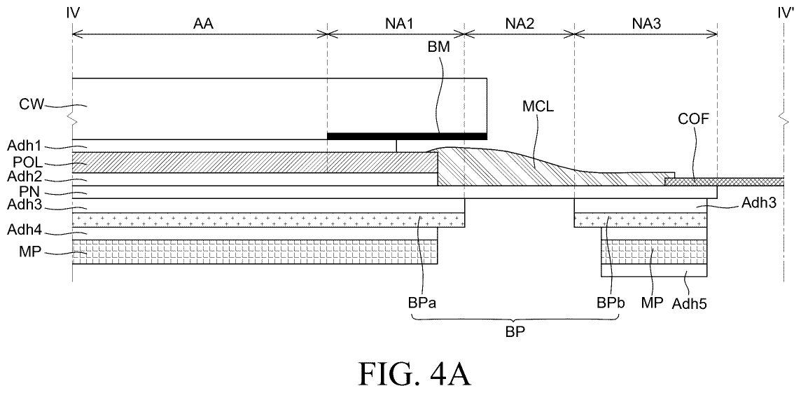

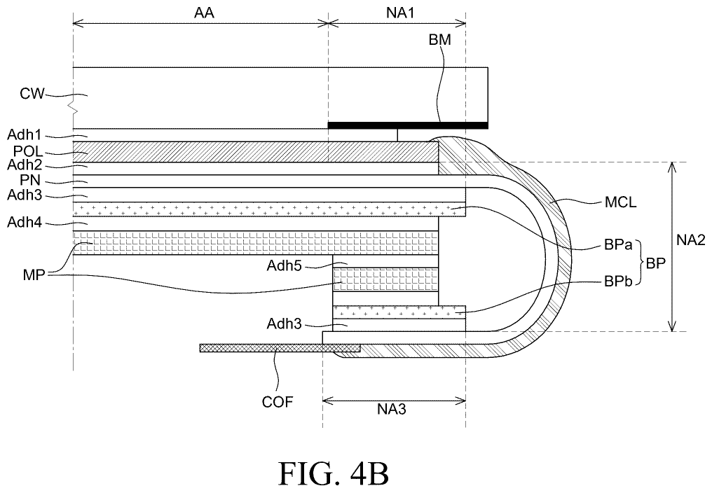

FIGS. 4A and 4B are cross-sectional views of a display apparatus according to an example embodiment of the present disclosure. Specifically, FIG. 4A is a view of a display apparatus 100 before being bent (e.g., along line IV-IV′ of FIG. 2) and FIG. 4B is a view of the display apparatus 100 after being bent. In FIG. 2, among various components of the display apparatus 100, a display panel PN, a polarizer POL, a flexible film COF, and a printed circuit board PCB are illustrated.

Referring to FIGS. 2 to 4B, the display apparatus 100 can include a cover member CW, a first adhesive layer Adh1, a polarizer POL, a second adhesive layer Adh2, a display panel PN, a third adhesive layer Adh3, a support member BP, a fourth adhesive layer Adh4, a conductive member MP, a fifth adhesive layer Adh5, a coating layer MCL, a flexible film COF, and a printed circuit board PCB. However, embodiments of the present application are not limited thereto, and one or more of these elements included in the display apparatus 100 can be omitted, and at least one additional element can be included in the display apparatus 100 when necessary.

First, referring to FIG. 2, in the display panel PN, an active area AA and a non-active area NA disposed to be adjacent to (for example, surround or enclose) at least a part of the active area AA are defined.

The active area AA is an area in which images are displayed in the display apparatus 100.

The non-active area NA can be an area where images are not displayed and extend from the active area AA. The non-active area NA includes a first non-active area NA1, a second non-active area NA2, and a third non-active area NA3.

For example, the first non-active area NA1 is an area adjacent to at least a part of the active area AA.

The second non-active NA2 is an area extending from the first non-active area NA1. The second non-active area NA2 is an area which is bent to minimize or reduce a bezel area. In the second non-active area NA2, a plurality of link lines which is connected to a plurality of pad electrodes of the third non-active area NA3 can be disposed.

The third non-active area NA3 is an area extending from the second non-active area NA2. As the second non-active area NA2 is bent, the third non-active area NA3 is disposed so as to be opposite to the active area AA and the first non-active area NA1. The third non-active area NA3 is an area in which a plurality of pad electrodes is disposed and at least one flexible films COF is bonded thereto.

The display panel PN includes a concave portion in the plan view. For example, in order to allow the second non-active area NA2 to be easily bent toward the rear surface of the display apparatus 100, a width of the second non-active area NA2 can be smaller than a width of the first non-active area NA1. A width of the second non-active area NA2 is different from a width of the first non-active area NA1. For example, both ends of the second non-active area NA2 can be disposed further inward than both ends of the first non-active area NA1.

The display panel PN can include a substrate and a light emitting diode.

The substrate is a support member for supporting other components disposed on the substrate of the display apparatus 100 and can be configured by an insulating material. For example, the substrate can be formed of glass or resin. Further, the substrate can be configured to include plastics such as polymer or polyimide (PI) or can be formed of a material having a flexibility. For example, the substrate can include a flexible polymer film which is made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto.

The light emitting diode can be disposed on the substrate. The light emitting diode can be defined in different manners depending on the type of the display panel PN. For example, when the display panel PN is an organic light emitting display panel, the light emitting diode can be an organic light emitting diode (OLED). The example embodiments of the present disclosure are not limited thereto.

A driving transistor can be disposed between the substrate and the light emitting diode to drive the light emitting diode. The driving transistor can be disposed in each of the plurality of sub-pixel areas. For example, the driving transistor includes a gate electrode, an active layer, a source electrode, and a drain electrode. The driving transistor can further include a gate insulating layer which insulates the gate electrode from the active layer and an interlayer insulating layer which insulates the gate electrode from the source electrode and the drain electrode. The driving transistor can be included as a part of the pixel circuit for driving the light emitting diode. In addition to the driving transistor, the pixel circuit can further include one or more switching transistors and at least one capacitor.

Referring to FIGS. 2 to 4B, a plurality of flexible films COF is disposed at one end of the display apparatus 100. For example, the plurality of flexible films COF can be disposed in the third non-active area NA3. The plurality of flexible films COF is films in which various components are disposed on a base film having malleability to supply a signal to the plurality of sub-pixels SP of the active area AA. One ends of the plurality of flexible films COF are disposed in the non-active area NA of the display apparatus 100 to supply a data voltage to the plurality of sub-pixels SP of the active area AA.

In the plurality of flexible films COF, a driver such as a gate driver or a data driver can be disposed. The driver can be disposed by a chip on glass (COG), a chip on film (COF), or a tape carrier package (TCP) technique depending on a mounting method, but is not limited thereto. In addition, shapes and a number of the plurality of flexible films COF illustrated in FIG. 2 are illustrative and the shapes and the number of the flexible films COF can be changed in various forms depending on the necessity, but are not limited thereto.

Referring to FIG. 2, the printed circuit board PCB is connected to the plurality of flexible films COF. The printed circuit board PCB is a component which supplies signals to the driving IC. Various components can be disposed in the printed circuit board PCB to supply various driving signals such as a driving signal or a data voltage to the driving IC.

Referring to FIGS. 2 to 4B, the polarizer POL can be disposed above the display panel PN. The polarizer POL is a layer for polarizing incident light and is a film having a predetermined level of light transmittance to absorb external light and reflected light thereof to suppress degradation of a contrast ratio. For example, degradation of a display quality due to reflected light of the external light is suppressed and a transmittance of an image of the display apparatus 100 is improved.

The polarizer POL is formed by aligning iodine (I) or a dichroic dye in a polyvinyl alcohol (PVA) resin in a stretching direction and an absorption axis is formed in the stretching direction. Accordingly, light which travels in a direction parallel to the absorption axis of the polarizer POL is absorbed and light which travels in a direction perpendicular to the absorption axis is selectively transmitted.

In addition, deformation of the polarizer POL can proceed along an optical absorption axis. Accordingly, a deformation rate of the polarizer POL can be proportional to a length of the optical absorption axis. Accordingly, a deformation rate of a portion of the polarizer POL with a shorter optical absorption axis is smaller than a deformation rate of a portion of the polarizer with a longer optical absorption axis.

Therefore, in order to minimize or reduce the deformation, the polarizer POL includes a plurality of concave portions POL_C disposed in the non-active area NA. A portion of the polarizer POL in which the plurality of concave portions POL_C is disposed has a small width so that the optical absorption axis is also short. For example, the part with a short optical absorption axis can have a smaller deformable width. Therefore, the plurality of concave portions POL_C can be disposed in an area of the display apparatus 100 having a high deformation rate. For example, the plurality of concave portions POL_C is disposed in a portion in which the bending stress is maximized or increased. For example, the plurality of concave portions POL_C is disposed on a boundary between the non-bending area and the bending area. For example, the plurality of concave portions POL_C is disposed between the active area AA and a second non-active area NA2 which is a bending area, in the first non-active area NA1 which is a non-bending area. For example, the plurality of concave portions POL_C is disposed so as to correspond to the boundary of the first non-active area NA1 which is a non-bending area and a second non-active area NA2 which is a bending area. Therefore, the plurality of concave portions POL_C is disposed so as to correspond to an end of the second non-active area NA2. For example, the plurality of concave portions POL_C is disposed to be adjacent to an area where an end of the first non-active area NA1 and an end of the second non-active area NA2 are orthogonal to each other, but is not limited thereto. At this time, a portion of the polarizer POL in which a center of the plurality of concave portions POL_C is disposed has a shortest optical absorption axis so that the center of the plurality of concave portions POL_C is disposed so as to correspond to the end of the second non-active area NA2.

The plurality of concave portions POL_C is formed in a semi-elliptical shape to be disposed only in the non-active area NA without overlapping the active area AA so as not to be visible to a user. Therefore, a minor axis (D2) direction of the plurality of concave portions POL_C is the same as a curved direction of the plurality of concave portions POL_C. For example, the minor axis (D2) direction of the plurality of concave portions POL_C is the same as a direction extending from the first non-active area NA1 to the second non-active area NA2. A ratio of the major axis D1 to the minor axis D2 of the plurality of concave portions POL_C is 10:1 or larger, and for example, in a range from 10:1 to 15:1, but is not limited thereto and can be designed in various ways without overlapping the active area AA.

Referring to FIGS. 4A and 4B, the second adhesive layer Adh2 is disposed between the polarizer POL and the display panel PN. The second adhesive layer Adh2 fixes the polarizer POL and the display panel PN. The second adhesive layer Adh2 can be an optically clear adhesive (OCA) or a transparent resin to allow the image of the display panel PN to be visible to the user, but is not limited thereto.

The cover member CW can be disposed on the polarizer POL. The cover member CW is a shape corresponding to the display panel PN and is disposed so as to cover the display panel PN. The cover member CW can protect the display panel PN from external shocks, moisture, and heat. For example, the cover member CW can be a tempered glass, but is not limited thereto.

The light shielding layer BM is disposed on a rear surface of the cover member CW. The light shielding layer BM is configured to shield at least a part of the non-active area NA. The light shielding layer BM can include a light shielding material, such as a pigment, a dye, and carbon black, and for example, can be coated with a black ink, but is not limited thereto.

Referring to FIGS. 3A to 4B, the first adhesive layer Adh1 is disposed between the polarizer POL and the cover member CW. The first adhesive layer Adh1 fixes the polarizer POL and the cover member CW. The first adhesive layer Adh1 can be an optically clear adhesive (OCA) or a transparent resin to allow the image of the display panel PN to be visible to the user, but is not limited thereto.

The coating layer MCL can be disposed on the display panel PN. Since a tensile force is applied to the wiring line disposed on the substrate during the bending to cause fine crack, the coating layer MCL can be coated in at least an area which is bent with a thin thickness to protect the wiring line. A thickness of the coating layer MCL is set according to the characteristic of the display apparatus 100 by considering a neutral plane of the display apparatus 100 in a curved portion, for example, an area to be bent. Therefore, for example, the coating layer MCL is disposed in a part of the first non-active area NA1, in the second non-active area NA2 and a part of the third non-active area NA3. Specifically, the coating layer MCL can be applied to overflow at least a part of the polarizer POL and the flexible film COF so as to overlap a part of the polarizer POL and a part of the flexible film COF. Therefore, the coating layer MCL can be disposed so as to overlap the plurality of concave portions POL_C of the polarizer POL. In addition, for the convenience of description, in the drawing, the hatching of the coating layer MCL is omitted in a portion where the polarizer POL and the coating layer MCL overlap, but is not limited to that illustrated in the drawing.

The support member BP can be disposed below the display panel PN. The support member BP supports the display panel PN and protects the display panel PN from external moisture, heat, and shocks. The support member BP suppresses curl and static electricity of the display apparatus 100 and is formed of a transparent organic insulating material to inspect an outer appearance of the rear surface of the display apparatus 100. For example, the support member BP can be formed of a plastic such as polymethyl methacrylate (PMMA), polycarbonate (PC), polyvinyl alcohol (PVA), acrylonitrile butadiene-styrene (ABS), polyethylene terephthalate (PET), silicone, or polyurethane (PU), but it is not limited thereto.

The support member BP includes a first support member BPa and a second support member BPb which are spaced apart from each other. For example, the first support member BPa is disposed so as to overlap the active area AA and the first non-active area NA1 and the second support member BPb is disposed to be spaced apart from the first support member BPa to overlap the third non-active area NA3. For example, the first support member BPa and the second support member BPb are disposed to be spaced apart from each other with respect to the second non-active area NA2.

At this time, the first support member BPa includes a first part and a second part. The first part is an area which overlaps the active area AA and a part of the first non-active area NA1 and the second part extends from the first part to the second non-active area NA2. The second non-active area NA2 has a width smaller than that of the first non-active area NA1 so that the second part which is disposed to overlap the second non-active area NA2 also has a width smaller than the first part which overlaps the first non-active area NA1. The second non-active area NA2 is a bending area so that the stress is concentrated on the end of the second part extending toward the second non-active area NA2. Therefore, the plurality of concave portions POL_C is disposed so as to correspond to a vertex of the second part of the first support member BPa.

The third adhesive layer Adh3 can be disposed between the display panel PN and the support member BP. The third adhesive layer Adh3 can fix the display panel PN and the support member BP. The third adhesive layer Adh3 can be formed of a pressure sensitive adhesive (PSA), but is not limited thereto.

The conductive member MP is disposed below the support member BP. The conductive member MP is spaced, similar to the support member BP, to be disposed below each of the first support member BPa and the second support member BPb. The conductive member MP protects the components of the display apparatus 100 from external shocks. Further, the conductive member MP serves as an earth to suppress the static electricity permeating the display apparatus 100 or easily discharge residual charges accumulated in the display apparatus 100 to the outside. Further, the conductive member MP easily discharges heat generated in the display apparatus 100 to the outside. The conductive member MP can be formed of a metal material having excellent thermal conductivity, electrical conductivity, and mechanical rigidity. For example, the conductive member MP can be configured by copper (Cu) or stainless steel (SUS), but is not limited thereto.

The fourth adhesive layer Adh4 is disposed between the support member BP and the conductive member MP. The fourth adhesive layer Adh4 fixes the support member BP and the conductive member MP. For example, the fourth adhesive layer Adh4 can be formed of a pressure sensitive adhesive (PSA), but is not limited thereto.

The fifth adhesive layer Adh5 is disposed to bond and fix the conductive member MP which is disposed to be spaced before bending the display apparatus 100, after bending. In FIG. 4A, it is illustrated that the fifth adhesive layer Adh5 is bent in an adhered state to the conductive member MP disposed below the second support member BPb, but is not limited thereto and is bent in a state bonded to the conductive member MP disposed below the first support member BPa. For example, the fifth adhesive layer Adh5 can be formed of a pressure sensitive adhesive (PSA), but is not limited thereto.

In the display apparatus, the polarizer is disposed on the display panel. The polarizer is a component for polarizing incident light and is a film having a predetermined level of light transmittance to absorb external light and reflected light thereof to suppress degradation of a contrast ratio. The polarizer has a relatively larger rate of expansion or contraction due to heat and humidity in the high temperature and high humidity environment, as compared with the other component of the display apparatus. Accordingly, various types of defects can occur on a boundary surface with the other components, due to the thermal deformation of the polarizer.

For example, as a first type of defect, a defect caused by the contraction of the polarizer can occur. As the polarizer contracts, a crack between the other component and the polarizer can be generated and the moisture permeates through the crack. The wiring line of the display panel is corroded or iodine (I) which is a component of the polarizer can be dissociated, due to the permeating moisture. Iodine (I) is particularly black as seen with the naked eye so that iodine (I) of the polarizer is dissociated, resulting in an image defect of the front surface of the display apparatus.

As a second type of defect, a defect caused by the direction difference in which the polarizer is thermally deformed can occur. For example, the curl phenomenon of the polarizer due to the direction difference of the contraction and expansion of the polarizer can occur. This leads to the lifting of the polarizer and the stress generated during the lifting affects the display panel, resulting in the deterioration in the display quality. At this time, a strain of the polarizer is proportional to the length of the optical absorption axis of the polarizer.

In addition, recently, studies are actively being conducted to reduce the bezel area to display the image in an area as large as possible within a limited size of the display apparatus. For example, the bezel area is bent to the rear surface of the display apparatus to minimize or reduce the bezel area which is visible to the user. However, in this case, the strain of the polarizer is increased due to the bending stress.

In the display apparatus 100 according to the example embodiment of the present disclosure, in order to minimize or reduce the bezel area, a part of the non-active area NA can be bent to the rear surface of the display apparatus 100. Therefore, in order to minimize or reduce the deformation of the polarizer POL due to the bending stress, the polarizer POL includes a plurality of concave portions POL_C disposed in the non-active area NA. For example, the polarizer POL includes the plurality of concave portions POL_C so that the length of the optical absorption axis is shortened so that the deformation which propagates along the optical absorption axis can be minimized, reduced or prevented. At this time, the plurality of concave portions POL_C is disposed in an area where the bending stress is concentrated. For example, in the display apparatus 100 according to the example embodiment of the present disclosure, the second non-active area NA2 and the third non-active area NA3 extending from the second non-active area NA2 are bent to the rear surface of the display apparatus 100. Therefore, the plurality of concave portions POL_C is disposed so as to correspond to the boundary of the first non-active area NA1 which is a non-bending area and a second non-active area NA2 which is a bending area. Specifically, the plurality of concave portions POL_C is disposed so as to correspond to the end of the second non-active area NA2 and a center of the plurality of concave portions POL_C having the shortest optical absorption axis is disposed so as to overlap the end of the second non-active area NA2 in a direction extending from the first non-active area NA1 to the second non-active area NA2. Accordingly, the deformation of the polarizer POL due to the bending stress can be minimized, reduced or prevented.

Therefore, in the display apparatus 100 according to the example embodiment of the present disclosure, the polarizer POL includes a plurality of concave portions POL_C so that the moisture permeation due to the contraction of the polarizer POL is blocked, thereby suppressing the corrosion of the wiring line. Further, the image defects caused by the dissociation of iodine (I) of the polarizer POL due to the moisture can be suppressed. Further, the curl phenomenon due to the direction difference of the contraction and the expansion of the polarizer POL is also minimized, reduced or prevented to suppress the lifting of the polarizer POL. Accordingly, in the display apparatus 100 according to the example embodiment of the present disclosure, the reliability and the display quality can be improved.

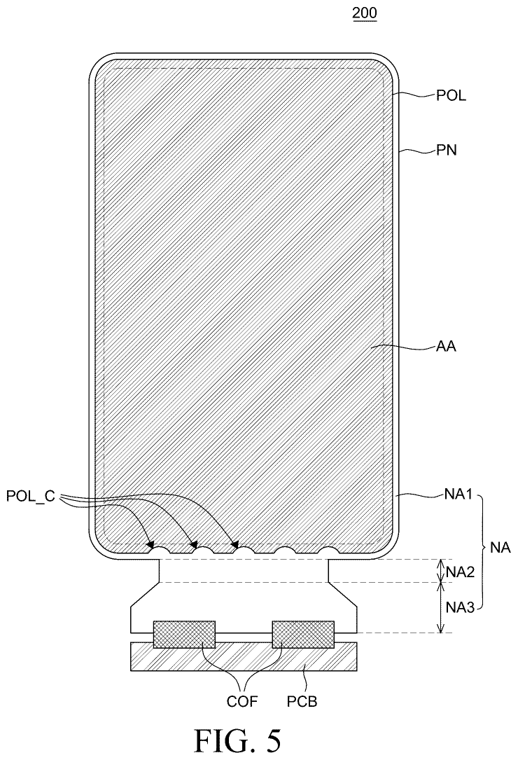

FIG. 5 is a schematic plan view of a display apparatus according to another example embodiment of the present disclosure. A main difference between a display apparatus 100 of FIG. 5 and the display apparatus 100 of FIGS. 1 to 4B is a polarizer POL, but the other components are substantially the same, so that a redundant description will be omitted or may be briefly provided.

Referring to FIG. 5, in order to minimize or reduce the deformation, the polarizer POL includes a plurality of concave portions POL_C disposed in the first non-active area NA1.

The plurality of concave portions POL_C shortens the width of the polarizer POL to minimize or reduce a deformable area. Therefore, the plurality of concave portions POL_C can be disposed in an area of the display apparatus 200 having a high deformation rate. For example, the plurality of concave portions POL_C is disposed in a portion in which the bending stress is maximized or relatively higher than other portions. Therefore, the plurality of concave portions POL_C is disposed on a boundary between the non-bending area and the bending area. Specifically, the plurality of concave portions POL_C is disposed so as to correspond to the boundary of the first non-active area NA1 which is a non-bending area and a second non-active area NA2 which is a bending area. Therefore, the plurality of concave portions POL_C is disposed so as to correspond to an end of the second non-active area NA2. For example, the plurality of concave portions POL_C is disposed to be adjacent to an area where an end of the first non-active area NA1 and an end of the second non-active area NA2 are orthogonal to each other, but is not limited thereto.

At this time, a center of the plurality of concave portions POL_C having the smallest width is disposed so as to overlap the end of the second non-active area NA2 in a direction extending from the first non-active area NA1 to the second non-active area NA2. For example, the center of the concave portion POL_C is disposed so as to correspond to the end of the second non-active area NA2 in which the bending stress is maximized or increased, to minimize or reduce the deformation of the polarizer POL.

Further, in the display apparatus 200 according to another example embodiment of the present disclosure, the concave portion POL_C can be disposed not only at both ends of the second non-active area NA2, but also disposed to be spaced apart from each other with a constant interval between both ends of the second non-active area NA2. For example, the concave portion POL_C can be additionally disposed so as to overlap the entire second non-active area NA2 which is an area to be bent, in a direction extending from the first non-active area NA1 to the second non-active area NA2.

Accordingly, unlike the concave portion POL_C disposed so as to correspond to the end of the second non-active area NA2, both ends of the concave portion POL_C disposed to correspond to the second non-active area NA2 can be disposed further inward than the end of the second non-active area NA2. Accordingly, the center of the concave portion POL_C having the smallest width is also disposed inside the first non-active area NA1 more than the end of the second non-active area NA2 so as to correspond to the second non-active area NA2. Therefore, the deformation of the polarizer POL due to the bending stress can be further effectively improved.

In the display apparatus 200 according to another example embodiment of the present disclosure, in order to minimize or reduce the bezel area, a part of the non-active area NA can be bent to the rear surface of the display apparatus 200. Therefore, in order to minimize or reduce the deformation of the polarizer POL due to the bending stress, the polarizer POL includes a plurality of concave portions POL_C disposed in the non-active area NA. For example, the polarizer POL includes the plurality of concave portions POL_C so that the length of the optical absorption axis is shortened so that the deformation which propagates along the optical absorption axis can be minimized, reduced or prevented. Therefore, the plurality of concave portions POL_C is disposed in an area where the bending stress is concentrated. For example, the plurality of concave portions POL_C is disposed so as to correspond to the boundary of the first non-active area NA1 which is a non-bending area and the second non-active area NA2 which is a bending area. For example, at least a part of the plurality of concave portions POL_C is disposed between the active area AA and a second non-active area NA2 which is a bending area, in the first non-active area NA1 which is a non-bending area. Specifically, the plurality of concave portions POL_C is disposed so as to correspond to the end of the second non-active area NA2 and a center of the plurality of concave portions POL_C having the shortest optical absorption axis is disposed so as to overlap the end of the second non-active area NA2 in a direction extending from the first non-active area NA1 to the second non-active area NA2. Accordingly, the deformation of the polarizer POL due to the bending stress can be minimized, reduced or prevented.

Further, in the display apparatus 200 according to another example embodiment of the present disclosure, the plurality of concave portions POL_C can be disposed not only in an area corresponding to an end of the second non-active area NA2, but also to correspond to the second non-active area NA2 between both ends of the second non-active area NA2. For example, a part of the plurality of concave portions POL_C is disposed to be constantly spaced apart from each other to overlap the entire second non-active area NA2 which is an area to be bent in a direction extending from the first non-active area NA1 to the second non-active area NA2. Therefore, the center of the concave portion POL_C having the smallest width is also disposed so as to overlap the second non-active area NA2 in a direction extending from the first non-active area NA1 to the second non-active area NA2. Accordingly, the deformation of the polarizer POL due to the bending stress can be more effectively improved. In addition, a concave portion POL_C disposed to correspond to an end of the second non-active area NA2 and another concave portion disposed between the ends of the second non-active area NA2 can have different dent depths. For example, a dent depth of the concave portion POL_C disposed to correspond to an end of the second non-active area NA2 can be larger than that of the another concave portion disposed between the ends of the second non-active area NA2. The dent depth of the concave portion can refer to a ratio of a minor axis to a major axis of the concave portion. In another example, although the plurality of concave portions POL_C is disposed in only a side of the first non-active area NA1 which is adjacent to the second non-active area NA2 as shown in FIGS. 2 to 5, but the present disclosure is not limited thereto. For example, the plurality of concave portions POL_C can also be disposed in one or more other side of the first non-active area NA1 in addition to the side which is adjacent to the second non-active area NA2.

For example, in the display apparatus 200 according to another example embodiment of the present disclosure, the polarizer POL includes a plurality of concave portions POL_C so that the moisture permeation due to the contraction of the polarizer POL is blocked, thereby suppressing the corrosion of the wiring line. Further, the image defects caused by the dissociation of iodine (I) of the polarizer POL due to the moisture can be suppressed. Further, the curl phenomenon due to the direction difference of the contraction and the expansion of the polarizer POL is also minimized, reduced or prevented to suppress the lifting of the polarizer POL. Accordingly, in the display apparatus 200 according to another example embodiment of the present disclosure, the reliability and the display quality can be improved.

The example embodiments of the present disclosure can also be described as follows:

According to an aspect of the present disclosure, there is provided a display apparatus. The display apparatus includes a display panel including an active area and a non-active area and a polarizer disposed on the display panel. The non-active area includes a first non-active area which is adjacent to at least a part of the active area, and a second non-active area which extends from the first non-active area to be bent. The polarizer includes a plurality of concave portions disposed between the active area and the second non-active area, in the first non-active area.

A width of the second non-active area can be smaller than a width of the first non-active area.

At least a part of the plurality of concave portions can be disposed so as to correspond to an end of the second non-active area.

A center of at least a part of the plurality of concave portions can be disposed so as to correspond to an end of the second non-active area.

The display apparatus can further include a coating layer which is disposed in the non-active area on the display panel and covers a part of the polarizer. The coating layer can overlap the plurality of concave portions.

The non-active area can further include a third non-active area which extends from the second non-active area and has a plurality of pad electrodes disposed therein.

The display apparatus can further include a support member disposed below the display panel. The support member can include a first support member which is disposed in the active area and the first non-active area and a second support member which is spaced apart from the first support member and is disposed in the third non-active area. The first support member can include a first part which overlaps the active area and a part of the first non-active area and a second part which extends from the first part to the second non-active area and has a width smaller than that of the first part. At least a part of the plurality of concave portions can be disposed so as to correspond to a vertex of the second part.

The display apparatus can further include a conductive member disposed below the support member. The conductive member can include a first part disposed under the first support member; and a second part disposed under the second support member and spaced apart from the first part of the conductive member.

The display apparatus can further include a cover member disposed on the polarizer; and a light shielding layer disposed on a rear surface of the cover member in a part of the non-active area.

The plurality of concave portions can have a semi-elliptical shape.

A ratio of a major axis to a minor axis of the plurality of concave portions can be in a range from 10:1 to 15:1.

A minor axis direction of the plurality of concave portions can be the same as a direction in which the plurality of concave portion is curved.

At least a part of the plurality of concave portions can be disposed so as to correspond to the second non-active area, in the first non-active area.

A center of at least a part of the plurality of concave portions can be disposed further inward than both ends of the second non-active area.

According to another aspect of the present disclosure, there is provided a display apparatus. The display apparatus includes a display panel including an active area and a non-active area and a polarizer attached to the display panel. The non-active area includes a first non-active area which is adjacent to at least a part of the active area, and a second non-active area which extends from the first non-active area to be bent. The polarizer can include a plurality of concave portions disposed adjacent to a boundary between the first non-active area and the second non-active area, in the first non-active area.

The plurality of concave portions can be adjacent to an area where an end of the first non-active area and an end of the second non-active area are orthogonal to each other.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display apparatus, comprising:
a display panel including an active area and a non-active area; and
a polarizer disposed on the display panel,
wherein the non-active area includes:
a first non-active area disposed adjacent to at least a part of the active area; and
a second non-active area extending from the first non-active area and configured to be bent, and
wherein the polarizer includes a plurality of concave portions disposed between the active area and the second non-active area, in the first non-active area.

2. The display apparatus according to claim 1, wherein a width of the second non-active area is smaller than a width of the first non-active area.

3. The display apparatus according to claim 1, wherein at least a part of the plurality of concave portions is disposed to correspond to an end of the second non-active area.

4. The display apparatus according to claim 1, wherein a center of at least a part of the plurality of concave portions is disposed to correspond to an end of the second non-active area.

5. The display apparatus according to claim 1, further comprising:
a coating layer disposed in the non-active area on the display panel and covering a part of the polarizer,
wherein the coating layer overlaps the plurality of concave portions.

6. The display apparatus according to claim 1, wherein the non-active area further includes a third non-active area extending from the second non-active area and having a plurality of pad electrodes disposed therein.

7. The display apparatus according to claim 6, further comprising:
a support member disposed below the display panel,
wherein the support member includes:
a first support member disposed in the active area and the first non-active area; and
a second support member spaced apart from the first support member and disposed in the third non-active area,
wherein the first support member includes:
a first part overlapping the active area and a part of the first non-active area; and
a second part extending from the first part to the second non-active area and having a width smaller than a width of the first part, and
wherein at least a part of the plurality of concave portions is disposed to correspond to a vertex of the second part.

8. The display apparatus according to claim 7, further comprising:
a conductive member disposed below the support member,
wherein the conductive member includes:
a first part disposed under the first support member; and
a second part disposed under the second support member and spaced apart from the first part of the conductive member.

9. The display apparatus according to claim 1, further comprising:
a cover member disposed on the polarizer; and
a light shielding layer disposed on a rear surface of the cover member in a part of the non-active area.

10. The display apparatus according to claim 1, wherein the plurality of concave portions have a semi-elliptical shape.

11. The display apparatus according to claim 10, wherein a ratio of a major axis to a minor axis of the plurality of concave portions is in a range from 10:1 to 15:1.

12. The display apparatus according to claim 10, wherein a minor axis direction of the plurality of concave portions is same as a direction in which the plurality of concave portions are curved.

13. The display apparatus according to claim 1, wherein at least a part of the plurality of concave portions is disposed to correspond to the second non-active area, in the first non-active area.

14. The display apparatus according to claim 13, wherein a center of at least a part of the plurality of concave portions is disposed further inward than both ends of the second non-active area.

15. The display apparatus according to claim 1, wherein the plurality of concave portions are adjacent to an area where an end of the first non-active area and an end of the second non-active area are orthogonal to each other.

16. A display apparatus, comprising:
a display panel including an active area and a non-active area; and
a polarizer attached to the display panel,
wherein the non-active area includes:
a first non-active area disposed adjacent to at least a part of the active area; and
a second non-active area extending from the first non-active area and configured to be bent, and
wherein the polarizer includes a plurality of concave portions disposed adjacent to a boundary between the first non-active area and the second non-active area, in the first non-active area.
